(19) United States
(12) Patent Application Publication
(10) Pub. No.: US 2025/0221298 A1
(43) Pub. Date: Jul. 3, 2025

(54) ELECTRONIC DEVICE

(71) Applicant: VisEra Technologies Company Limited, Hsin-Chu City (TW)

(72) Inventors: Hsuan-Chun CHANG, Hsin-Chu City (TW); Lai-Hung LAI, Hsin-Chu City (TW); Chin-Chuan HSIEH, Hsin-Chu City (TW)

(21) Appl. No.: 18/399,179

(22) Filed: Dec. 28, 2023

(51) Int. Cl. H10K 85/40; H10K 71/16; H10K 102/10

(52) U.S. Cl. CPC H10K 85/40; H10K 71/164; H10K 2102/103

(57) ABSTRACT

An electronic device includes a first electrode; a second electrode on the first electrode; a semiconductor layer between the first electrode and the second electrode; and a first self-assembled monolayer between the first electrode and the semiconductor layer. The first self-assembled monolayer includes a compound represented by Formula (1) below:

$$X - {R}^{2} - {Si ( {OR}^{1} )}_{3} , \qquad ( 1 )$$

wherein in Formula (1), R¹ are each independently a C₁-C₅ alkyl group; R² is a C₁-C₂₀ alkylene group; and X is an electron withdrawing group.

### BACKGROUND OF THE INVENTION

### Field of the Invention

The present disclosure relates to an electronic device, and, in particular, to an electronic device having a self-assembled monolayer.

### Description of the Related Art

With the advancement of science and technology, sales of various electronic devices are booming. Common electronic devices include an organic light-emitting diode (OLED), a light-emitting diode (LED), a phototransistor, a photovoltaic cell, an organic photodetector (OPD), etc.

The organic photodetector that has an organic semiconductor as a photosensitive layer can convert optical signals into electronic signals, which are widely used in optical communications, environmental monitors, cameras, smartphones, image sensors, and the like.

The detection sensitivity of the organic photodetector depends critically on the external quantum efficiency (EQE) of the organic photodetector and a dark current in the organic photodetector. The EQE of the organic photodetector is an ability of the organic photodetector to convert a light energy into an electrical energy. The dark current is one of the main causes of a poor signal-to-noise ratio (SNR) of the organic photodetector. The detection sensitivity of the organic photodetector can be improved by improving the EQE of the organic photodetector or by reducing the dark current in the organic photodetector.

### BRIEF SUMMARY OF THE INVENTION

The present disclosure provides an electronic device having a self-assembled monolayer.

According to an aspect of the present disclosure, there is provided an electronic device includes a first electrode; a second electrode on the first electrode; a semiconductor layer between the first electrode and the second electrode; and a first self-assembled monolayer between the first electrode and the semiconductor layer. The first self-assembled monolayer includes a compound represented by Formula (1) below:

X—R²—Si(OR¹)₃ (1),
wherein in Formula (1), R¹ are each independently a C₁-C₅ alkyl group; R² is a C₁-C₂₀ alkylene group; and X is an electron withdrawing group.

### BRIEF DESCRIPTION OF THE DRAWINGS

The present disclosure can be more fully understood by reading the subsequent detailed description and examples with references made to the accompanying drawings, wherein:

FIG. 1 schematically illustrates a structure of an electronic device according to an embodiment.

FIG. 2 schematically illustrates a structure of an electronic device according to an embodiment.

FIG. 3 schematically illustrates a structure of an electronic device according to an embodiment.

### DETAILED DESCRIPTION OF THE INVENTION

The electronic device of the present disclosure is described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. In addition, in this specification, expressions such as “first material layer disposed on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer or section. Thus, a first element, component, region, layer, portion or section discussed below could be termed a second element, component, region, layer, portion or section without departing from the teachings of the present disclosure.

In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

The terms “about” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

The term “C₁-C₅ alkyl group” used herein refers to a straight or branched aliphatic hydrocarbon monovalent group having 1 to 5 carbon atoms in the main carbon chain thereof. Non-limiting examples of the C₁-C₅ alkyl group include, but is not limited to, a methyl group, an ethyl group, a propyl group, an isobutyl group, a sec-butyl group, a tert- butyl group, and a pentyl group.

The term “C₁-C₂₀ alkylene group” used herein refers to a straight or branched aliphatic hydrocarbon divalent group having 1 to 20 carbon atoms in the main carbon chain thereof. Non-limiting examples of the C₁-C₂₀ alkylene group include, but is not limited to, a methylene group, an ethylene group, a propylene group, an isobutylene group, a sec-butylene group, a tert-butylene group, a pentylene group, an isoamylene group, and a hexylene group.

The term “C₂-C₂₀ alkynyl group” used herein refers to a C₂-C₂₀ alkyl group having at least one carbon-carbon triple bond in the center or at a terminal thereof. Non- limiting examples of the C₂-C₂₀ alkynyl group include, but is not limited to, an ethenyl group and a propynyl group.

The term “C₆-C₂₀ aryl group” or “unsubstituted C₆-C₂₀ aryl group” used herein refers to a monovalent group having a carbocyclic aromatic system containing 6 to 20 carbon atoms. Non-limiting examples of the C₆-C₂₀ aryl group or the unsubstituted C₆-C₂₀ aryl group include but not limited to a phenyl group, a naphthyl group, an anthracenyl group, and a phenanthrenyl group. The term “substituted C₆-C₂₀ aryl group” used herein refers to a monovalent group that at least one hydrogen atom on the C₆-C₂₀ aryl group or the unsubstituted C₆-C₂₀ aryl group is substituted with a hydroxyl group, a deuterium atom, a tritium atom, a halogen atom, amine, O, N, S, —CN, or a C₁-C₅ alkyl group.

The following description is made for the purpose of illustrating the general principles of the disclosure and should not be taken in a limiting sense. The scope of the disclosure is best determined by reference to the appended claims.

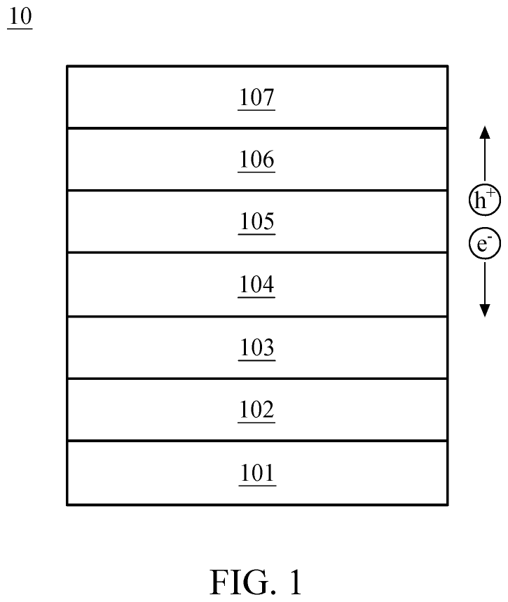

FIG. 1 schematically illustrates a structure of an electronic device 10 according to an embodiment.

Referring to FIG. 1, the electronic device 10 includes a first electrode 101, a second self-assembled monolayer 102, a hole-blocking layer 103, a first self-assembled monolayer 104, a semiconductor layer 105, an electron blocking layer 106, and a second electrode 107.

The first electrode 101 may be an electron injection electrode. The material used to form the first electrode 101 may be a material having a work function higher than the material included in the second electrode 107. The first electrode 101 may include a surface including hydroxyl groups. In some embodiments, the first electrode 101 may include a transparent conductive oxide. Non-limiting examples of the transparent conductive oxide may include, but is not limited to, indium tin oxide (ITO), indium zinc oxide (IZO), tin oxide (SnO₂), and zinc oxide (ZnO). In some embodiments, the first electrode 101 may include indium tin oxide (ITO).

The second electrode 107 may be a hole injection electrode. The material used to form the second electrode 107 may be a metal, an alloy, an electro-conductive compound, or a mixture thereof. Non-limiting examples of the material for forming the second electrode 107 may include, but is not limited to, silver (Ag), lithium (Li), magnesium (Mg), aluminum (Al), aluminum (Al)-lithium (Li), calcium (Ca), magnesium (Mg)-indium (In), magnesium (Mg)-silver (Ag), indium tin oxide (ITO) or indium zinc oxide (IZO). The second electrode 107 may be disposed on the first electrode 101, and the second self-assembled monolayer 102, the hole-blocking layer 103, the first self-assembled monolayer 104, the semiconductor layer 105, and the electron blocking layer 106 may be disposed between the second electrode 107 and the first electrode 101.

The semiconductor layer 105 may be between the first electrode 101 and the second electrode 107. The semiconductor layer 105 may include an electron donor material and an electron acceptor material.

The electron donor material may include a material selected from a group consisting of a conjugated polymer; a diketopyrrolopyrrole-based material; a 4,8-bis(5-(2-ethylhexyl)thiophen-2-yl)benzo[1,2-b: 4,5-b′]dithiophene-based material; a 2,1,3-benzoselenadiazole-based material; a 2,1,3-benzothiadiazole-based material; or a combination thereof. Non-limiting examples of the diketopyrrolopyrrole-based material may include, but not limited to, poly[[4-(2-ethylhexyl)-4Hdithieno[3,2-b:20,30-d] pyrrole-2,6-diyl]-alt-2,5-selenophenediyl[2,5-bis (2 ethylhexyl)-2,3,5,6-tetrahydro-3,6-dioxopyrrolo[3,4-c]-pyrr-ole-1, 4-diyl]-2,5-selenophenediyl] (PDPPDSTPS), diketopyrrolopyrrole-quintetthiophene copolymer (PDPP5T), diketopyrrolopyrrole-terthiophene copolymer (PDPP3T), and dithienopyran-diketopyrrolopyrrole copolymer (PDTP-DPP). Non-limiting examples of the 4,8-bis(5-(2-ethylhexyl)thiophen-2-yl)benzo[1,2-b:4,5-b′]dithiophene-based material may include, but not limited to, Poly[(2,6-(4,8-bis(5-(2-ethylhexyl)thiophen-2-yl)-benzo[1,2-b:4,5-b′]dithiophene))-alt-(5,5-(1′,3′-di- 2-thienyl-5′,7′-bis(2-ethylhexyl)benzo[1′,2′-c:4′,5′-c′]dithiophene-4,8-dione)] (PBDB-T), Poly[(2,6-(4,8-bis(5-(2-ethylhexyl-3-fleoro)thiophen-2-yl)-benzo[1,2-5:4,5- 5′]dithiophene))-alt-(5,5-(1′,3′-di-2-thienyl-5′,7′-bis(2-ethylhexyl)benzo[1′,2′-c:4′,5′- c′]dithiophene-4,8-dione)] (PM6), and_ Poly{4,8-bis[5-(2-ethylhexyl)thiophen-2- yl]benzo[1,2-b:4,5-b′]-dithiophene-2,6-diyl-alt-3-fluoro-2-[(2-ethylhexyl)carbonyl]- thieno[3,4-b]thiophene-4,6-diyl} (PTB7-Th). Non-limiting examples of the 2,1,3-benzoselenadiazole-based material may include, but is not limited to, selenophene π-bridged copolymer (PCz-DSeBSe). Non-limiting examples of the 2,1,3-benzothiadiazole-based material may include, but not limited to, poly-[(4,4′-(bis-(hexyldecyl-sulfanyl)-methylene)-cyclopenta-[2,1-b:3,4-b′]-dithiophene)-alt- (benzo-[c]-[1,2,5]-thiadiazole)] (PCPDTSBT), Poly[2,6-(4,4-bis-(2-ethylhexyl)-4H- cyclopenta[2,1-b;3,4-b′]dithiophene)-alt4,7(2,1,3-benzothiadiazole)] (PCPDTBT), Poly[N-9′-heptadecanyl-2,7-carbazole-alt-5,5-(4′,7′-di-2-thienyl-2′,1′,3′-benzothiadiazole)] (PCDTBT), and Poly[(5,6-difluoro-2,1,3-benzothiadiazol-4,7-diyl)-alt-(3,3′″-di (2- octyldodecyl)-2,2′;5′,2″;5″,2′″-quaterthiophen-5,5′″-diyl)] (PffBT4T-2OD).

The electron acceptor material may include a material selected from a group consisting of a fullerene material; an indacenodithienothiophene (IDTT)-based material; a rhodanine-based material; Y6 (2,2′-((2Z,2′Z)-((12,13-bis(2-ethylhexyl)-3,9-diundecyl- 12,13-dihydro-[1,2,5]thiadiazolo[3,4-e]thieno[2″,3″:4′,5′]thieno[2′,3′:4,5]pyrrolo[3,2- g]thieno[2′,3′: 4,5]thieno[3,2-b]indole-2,10-diyl)bis(methanylylidene))bis(5,6-difluoro-3- oxo-2,3-dihydro-1H-indene-2,1-diylidene))dimalononitrile, BTPTT-4F); or a combination thereof. The fullerene material is an allotrope of carbon whose molecule consists of carbon atoms connected by single and double bonds so as to form a closed or partially closed mesh. The fullerene material may include 60 to 80 carbon atoms. Non-limiting examples of the fullerene material may include, but is not limited to, [6,6]-phenyl-C61-butyric acid methyl ester (PC61BM), [6,6]-[6,6]-phenyl-C71-butyric acid methyl ester (PC71BM), and indene-C60bisadduct (IC60BA). The indacenodithienothiophene-based material, the rhodanine- based material, and the Y6 are non-fullerene materials. Non-limiting examples of the indacenodithienothiophene-based material may include, but not limited to indacenodithiophene end-capped with 1.1-dicyanomethylene-3-indanone (IDIC), 2,2′- ((2Z,2′Z)-(((4,4,9,9-tetrakis(4-hexylphenyl)-4,9-dihydro-sindaceno[1,2-b:5,6- b′]dithiophene-2,7-diyl)bis(4-((2-ethylhexyl)oxy)thiophene-5,2- diyl))bis(methanylylidene))bis(5,6-difluoro-3-oxo-2,3-dihydro-1H-indene-2,1- diylidene))dimalononitrile (IEICO-4F), 2,2′-[4,4,11,11-tetrakis(4-hexylphenyl)-4,11- dihydrothieno[2′,3′:4,5]thieno[2,3- d]thieno[2″″,3″″:4′″,5′″]thieno[2′″,3′″:4″,5″]pyrano[2″,3″:4′,5′]thieno[2′,3′:4,5]thi eno[3,2-b]pyran-2,9-diyl]bis[methylidyne(5,6-difluoro (COi8DFIC), and 3,9-bis(2- methylene-((3-(1,1-dicyanomethylene)-6,7-difluoro)-indanone))-5,5,11,11-tetrakis(4- hexylphenyl)-dithieno[2,3-d:2′,3′-d′]-s-indaceno[1,2-b:5,6-b′]dithiophene (ITIC-4F). Non- limiting examples of the rhodanine-based material may include, but is not limited to, (5Z,5′Z)-5,5′-((7,7′-(4,4,9,9-tetraoctyl-4,9-dihydro-s-indaceno[1,2-b:5,6-b′]dithiophene- 2,7-diyl)bis(benzo[c][1,2,5]thiadiazole-7,4-diyl))bis(methanylylidene))bis(3-ethyl-2- thioxothiazolidin-4-one) (O-IDTBR), and (5Z,5′Z)-5,5′-((7,7′-(6,6,12,12-Tetraoctyl-6,12- dihydroindeno[1,2-b]fluorene-2,8-diyl)bis(benzo[c][1,2,5]thiadiazole-7,4- diyl))bis(methanylylidene))bis(3-ethyl-2-thioxothiazolidin-4-one) (IDFBR).

The electron blocking layer 106 may be disposed between the semiconductor layer 105 and the second electrode 107. The electron blocking layer 106 may be a layer having a good electron blocking ability. Therefore, the dark current in the electronic device 10 may be greatly suppressed by the electron blocking layer 106. The electron blocking layer 106 may comprises a material selected from a group consisting of nickel oxide (NiO); 2,9- bis[3-(dimethyloxidoamino)propyl]anthra[2,1,9-def:6,5, 10-d′e′f′]diisoquinoline- 1,3,8,10(2H,9H)-tetrone (PDINO); poly[[2,7-bis(2-ethylhexyl)-1,2,3,6,7,8-hexahydro- 1,3,6,8-tetraoxobenzo[lmn][3,8]phenanthroline-4,9-diyl]-2,5-thiophenediyl[9,9- bis[3′((N,N-dimethyl)-N-ethylammonium)]-propyl]-9H-fluorene-2,7-diyl]-2,5- thiophenediyl] (PNDIT-F3N-Br); poly[(9,9-bis(3′-((N,N-dimethyl)-N-ethylammonium)- propyl)-2,7-fluorene)-alt-2,7-(9,9-dioctylfluorene)]dibromide (PFN-Br); or a combination thereof, but the disclosure is not limited thereto. In some embodiments, the electron blocking layer 106 may include NiO. In some embodiments, the electron blocking layer 106 may further include a non-polar solvent. Non-limiting examples of the non-polar solvent may include, but is not limited to, cyclohexane, carbon tetrachloride, trichloroethylene, benzene, toluene, dichloromethane, xylene, and ethyl acetate.

The hole-blocking layer 103 may be disposed between the semiconductor layer 105 and the first electrode 101. The hole-blocking layer 103 may be a layer having a good hole blocking ability. Therefore, the dark current in the electronic device 10 may be greatly suppressed by the hole-blocking layer 103. The hole-blocking layer 103 may include a surface including hydroxyl groups. The material used to form the hole-blocking layer 103 may be selected from a group consisting of aluminum-doped zinc oxide (AZO); poly{9,9- dimethyl-10-(9-(4-vinylbenzyl)-9H-carbazol-3-yl)-9,10-dihydroacridine} (P-CzAc); N-([1,1′-biphenyl]-4-yl)-N-(4-(dibenzo [b,d] thiophen-2-yl) phenyl)dibenzo[b,d]thiophen-2- amine (DBTA); 3,5-di-9H-carbazol-9-yl-N,N-bis[4-[6-[(3-ethyl-3- oxetanyl)methoxy]hexyl]oxy]phenyl]benzenamine (Oxe-DCDPA); poly[(9,9- dioctylfluorenyl-2,7-diyl)-co-(4,4′-(N-(diphenylamine))-(2-cyanoisopropylphenyl))] (iPrCNp/pCNPr-TFB); N4,N4-di(biphenyl-4-yl)-N4′-(naphthalen-1-yl)-N4′-phenyl- biphenyl-4,4′-diamine; 2,2′-dimethyl-N4,N4,N4′,N4′-tetra-m-tolylbiphenyl-4,4′-diamine; 2,2′-bis(N,N-di-phenyl-amino)-9,9-spirobifluorene; 2,2′-bis[N,N-bis(biphenyl-4-yl)amino]- 9,9-spirobifluorene; N,N′-bis(phenanthren-9-yl)-N,N′-bis(phenyl)-benzidine; 2,2′,7,7′- tetrakis[N-naphthalenyl(phenyl)-amino]-9,9-spirobifluorene; N4,N4′-bis(9,9-dimethyl-9H- fluoren-2-yl)-N4,N4′-diphenylbiphenyl-4,4′-diamine; tris(phenylpyrazole)iridium; 2,2′,7,7′-tetrakis(N,N-diphenylamino)-2,7-diamino-9,9-spirobifluorene; N,N′- bis(naphthalen-1-yl)-N,N′-bis(phenyl)-2,7-diamino-9,9-diphenyl-fluorine; N,N′-bis(3- methylphenyl)-N,N′-bis(phenyl)-2,7-diamino-9,9-diphenyl-fluorine; N,N′-bis(naphthalen- 1-yl)-N,N′-bis(phenyl)-2,7-diamino-9,9-dimethyl-fluorine; N,N′-bis(3-methylphenyl)- N,N′-bis(phenyl)-2,7-diamino-9,9-dimethyl-fluorine; 9,10-dihydro-9,9-dimethyl-10-(9- phenyl-9H-carbazol-3-yl)-acridine; 4,4′-(diphenylmethylene)bis(N,N-diphenylaniline); N4,N4′-di(naphthalen-1-yl)-N4-(4-octylphenyl)-N4′-phenylbiphenyl-4,4′-diamine; poly[N,N′-bis(4-butylphenyl)-N,N′-bis(phenyl)-benzidine]; N,N′-bis(naphthalen-1-yl)- N,N′-bis(phenyl)-2,2′-dimethylbenzidine; or a combination thereof, but the disclosure is not limited thereto. In some embodiments, the hole-blocking layer 103 may include AZO.

The first self-assembled monolayer 104 may be disposed between the hole- blocking layer 103 and the semiconductor layer 105. In some embodiments, the first self- assembled monolayer 104 may have a thickness of 1-10 nm, 1-8 nm, or 2-5 nm. In some embodiments, the first self-assembled monolayer 104 may be formed by a vacuum vapor deposition process such that the layer under the first self-assembled monolayer 104 may not be destroyed.

The first self-assembled monolayer 104 may include a compound represented by Formula (1) below:

X—R²—Si(OR¹)₃ (1),
wherein in Formula (1), R¹ are each independently a C₁-C₅ alkyl group; R² is a C₁-C₂₀alkylene group; and X is an electron withdrawing group.

In some embodiments, R² is a C₁-C₁₈ alkylene group, a C₂-C₁₀ alkylene group, or a C₂-C₅ alkylene group. In some embodiments, R² is an ethylene group.

In some embodiments, R¹ are each independently a methyl group or an ethyl group. In some embodiments, the three R¹ may be the same. In some embodiments, all of the three R¹ are ethyl groups, but the disclosure is not limited thereto. The moiety of —OR¹ of the compound represented by Formula (1) may form a good chemical bond with the hydroxyl groups on the surface of the hole-blocking layer 103. Therefore, the first self-assembled monolayer 104 may be firmly formed on the hole-blocking layer 103 due to the chemical bond between the compound represented by Formula (1) and the surface of the hole-blocking layer 103.

In some embodiments, the lowest unoccupied molecular orbital (LUMO) energy of the hole-blocking layer 103 is between that of the electron acceptor material in the semiconductor layer 105 and the first electrode 101, such that the electrons injected from the first electrode 101 can easily reach the semiconductor layer 105 by disposing the hole- blocking layer 103 between the semiconductor layer 105 and the first electrode 101. The electron withdrawing group indicates a group drawing electrons from neighboring atoms towards itself. The compound represented by Formula (1) having an electron withdrawing group can prohibit electron injected from the first electrode 101 to the semiconductor layer 105 and the second electrode 107. Therefore, a work function of the electronic device 10 can be tuned and the dark current in the electronic device 10 can be reduced. In some embodiments, the electron withdrawing group is a group having an electronegativity between 0-4. In some embodiments, the electron withdrawing group is selected from a group consisting of a hydroxyl group, a C₂-C₂₀ alkynyl group, —NO₂, —CN, —CF₃, —CCl₃, —CBr₃, —CI₃, and —COOH, but the disclosure is not limited thereto.

The second self-assembled monolayer 102 may be disposed between the first electrode 101 and the hole-blocking layer 103, and the second self-assembled monolayer 102 may be different from the first self-assembled monolayer104. In some embodiments, the second self-assembled monolayer 102 may have a thickness of 1-10 nm, 1-8 nm, or 2-5 nm. In some embodiments, the second self-assembled monolayer 102 may be formed by a vacuum vapor deposition process.

The second self-assembled monolayer 102 may include a compound represented by Formula (2) below:

Ar—R⁴—Si(OR³)₃ (2),
wherein in Formula (2), R³ are each independently a C₁-C₅ alkyl group; R⁴ is a C1-C20 alkylene group; and Ar is a group including a resonance structure.

In some embodiments, R⁴ is a C₁-C₁₈ alkylene group, a C₂-C₁₀ alkylene group, or a C₂-C₅ alkylene group. In some embodiments, R⁴ is an ethylene group.

In some embodiments, R³ are each independently a methyl group or an ethyl group. In some embodiments, the three R³ may be the same. In some embodiments, all of the three R³ are ethyl groups, but the disclosure is not limited thereto. The moiety of —OR³ of the compound represented by Formula (2) may form a good chemical bond with the hydroxyl groups on the surface of the first electrode 101. Therefore, the compound represented by Formula (2) may be firmly formed on the first electrode 101 due to the chemical bond between the compound represented by Formula (2) and the surface of the first electrode 101.

The group including a resonance structure indicates a group which can be represented by two or more Lewis structures that differ only in the placement of electrons. In some embodiments, Ar is a substituted or unsubstituted C₆-C₂₀ aryl group. In some embodiments, the substituted C₆-C₂₀ aryl group may have at least one substituent, which is selected from a group consisting of a hydroxyl group, a deuterium atom, a tritium atom, a halogen atom, —CN, and a C₁-C₅ alkyl group, but the disclosure is not limited thereto. When the substituted C₆-C₂₀ aryl group has 2 or more substituents, the 2 or more substituents may be the same or different from each other. In some embodiments, the compound represented by Formula (2) may be a compound selected from a group consisting of pentafluorophenyl triethoxysilane, phenyl triethoxysilane, pentafluorophenyl trimethoxysilane, and phenyl trimethoxysilane, but the disclosure is not limited thereto. The electrons from the semiconductor layer 105 can be collected in the second self-assembled monolayer 102 due to a resonance effect of the group including a resonance structure in the compound represented by Formula (2). Therefore, the EQE of the electronic device 10 can be improved by the second self-assembled monolayer 102.

The structure of the electronic device of the present disclosure has been described in conjunction with the FIG. 1. However, the structure of the electronic device of the disclosure is not limited thereto. In some embodiments, the second self-assembled monolayer 102 and/or the hole-blocking layer 103 in the electronic device 10 may be omitted.

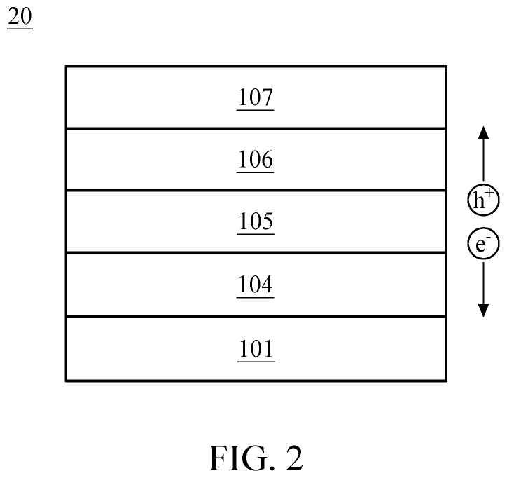

FIG. 2 schematically illustrates a structure of an electronic device 20 according to an embodiment. Referring to FIG. 2, the electronic device 20 includes a first electrode 101, a first self-assembled monolayer 104, a semiconductor layer 105, an electron blocking layer 106, and a second electrode 107. The main difference between the electronic device 10 and the electronic device 20 is that the second self-assembled monolayer 102 and the hole- blocking layer 103 are omitted from the electronic device 20. The moiety of —OR¹ of the compound represented by Formula (1) included in the first self-assembled monolayer 104 may form a good chemical bond with the hydroxyl groups on the surface of the first electrode 101 instead of the hydroxyl groups on the surface of the hole-blocking layer 103. The first self-assembled monolayer 104 may firmly formed on the first electrode 101 due to the chemical bond between the compound represented by Formula (1) and the surface of the first electrode 101. The first electrode 101, the first self-assembled monolayer 104, the semiconductor layer 105, an electron blocking layer 106, and the second electrode 107 of the electronic device 20 are substantially the same as that of the electronic device 10, so the descriptions thereof are not repeated herein.

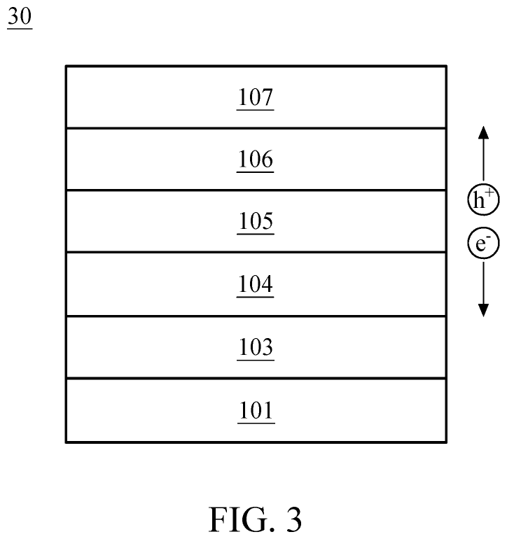

FIG. 3 schematically illustrates a structure of an electronic device 30 according to an embodiment. Referring to FIG. 3, the electronic device 30 includes a first electrode 101, a hole-blocking layer 103, a first self-assembled monolayer 104, a semiconductor layer 105, an electron blocking layer 106, and a second electrode 107. The main difference between the electronic device 10 and the electronic device 30 is that the second self-assembled monolayer 102 is omitted from the electronic device 30. The first electrode 101, the hole-blocking layer 103, the first self-assembled monolayer 104, the semiconductor layer 105, an electron blocking layer 106, and the second electrode 107 of the electronic device 30 are substantially the same as that of the electronic device 10, so the descriptions thereof are not repeated herein.

Specific embodiments are provided below to further illustrate features and advantages of the present disclosure. However, those skilled in the art should understand that the present disclosure is not limited to the specific embodiments disclosed below.

### Example 1

Indium tin oxide (ITO) was formed on a glass substrate to manufacture a first electrode which was used as an anode. A compound represented by Formula (1a) was formed on the first electrode by a vacuum vapor deposition process to manufacture a first self- assembled monolayer having a thickness of 2-3 nm. A photosensitive material was formed on the first self-assembled monolayer to manufacture a semiconductor layer. Nickel oxide (NiO) was formed on the semiconductor layer to manufacture an electron blocking layer.

Silver (Ag) was formed on the electron blocking layer to manufacture a second electrode which was used as a cathode, thereby completing the manufacture of an electronic device.

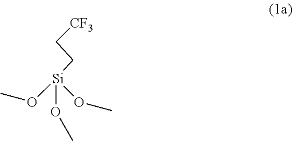

### Example 2

Indium tin oxide (ITO) was formed on a glass substrate to manufacture a first electrode which was used as an anode. Aluminum-doped zinc oxide (AZO) was formed on the first electrode to manufacture a hole-blocking layer. A compound represented by Formula (la) was formed on the hole-blocking layer by a vacuum vapor deposition process to manufacture a first self-assembled monolayer having a thickness of 2-3 nm. A photosensitive material was formed on the first self-assembled monolayer to manufacture a semiconductor layer. Nickel oxide (NiO) was formed on the semiconductor layer to manufacture an electron blocking layer. Then, silver (Ag) was formed on the electron blocking layer to manufacture a second electrode which was used as a cathode, thereby completing the manufacture of an electronic device.

### Example 3

Indium tin oxide (ITO) was formed on a glass substrate to manufacture a first electrode which was used as an anode. A compound represented by Formula (2a) was formed on the first electrode by a vacuum vapor deposition process to manufacture a second self- assembled monolayer having a thickness of 2-3 nm. Aluminum-doped zinc oxide (AZO) was formed on the second self-assembled monolayer to manufacture a hole-blocking layer. A compound represented by Formula (1a) was formed on the hole-blocking layer by a vacuum vapor deposition process to manufacture a first self-assembled monolayer having a thickness of 2-3 nm. A photosensitive material was formed on the first self-assembled monolayer to manufacture a semiconductor layer. Nickel oxide (NiO) was formed on the semiconductor layer to manufacture an electron blocking layer. Then, silver (Ag) was formed on the electron blocking layer to manufacture a second electrode which was used as a cathode, thereby completing the manufacture of an electronic device.

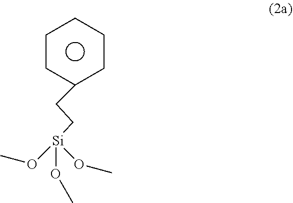

### Comparative Example

An electronic device was manufactured in the same manner as in Example 2, except that the first self-assembled monolayer was omitted.

### Evaluation Example

Dark current density (J_{d}), external quantum efficiency (EQE), and specific detectivity (D*) of the electronic devices of Examples 1 to 3 and the Comparative Example were measured using a home-built optical system. The results are shown in Table 1 below.

TABLE 1

| | J_{d} (A/cm²) | EQE (%) | D* (Jones) |
|---|---|---|---|
| Comparative Example | 2.5 × 10⁻⁷ ± 2.2 × 10⁻⁸ | 49.4 ± 8.1 | 9.7 × 10¹¹ ± 2.4 × 10¹¹ |
| Example 1 | 7.8 × 10⁻⁷ ± 0.7 × 10⁻⁸ | 57.3 ± 2.0 | 1.0 × 10¹² ± 1.3 × 10¹² |
| Example 2 | 5.8 × 10⁻⁸ ± 0.7 × 10⁻⁸ | 56.4 ± 2.6 | 3.6 × 10¹² ± 1.6 × 10¹² |
| Example 3 | 6.1 × 10⁻⁸ ± 0.8 × 10⁻⁸ | 61.4 ± 2.9 | 3.9 × 10¹² ± 1.4 × 10¹² |

Referring to Table 1, the electronic devices of Examples 2 and 3 are found to have lower dark current density, higher external quantum efficiency, and higher specific detectivity than the electronic device of the Comparative Example. The electronic device of Example 1 was found to have a higher external quantum efficiency and a higher specific detectivity than the electronic device of Comparative Example.

From the results shown in Table 1, it can be concluded that an electronic device including the first self-assembled monolayer according to the disclosure can have a high external quantum efficiency and a high specific detectivity. An electronic device including the hole-blocking layer and the first self-assembled monolayer according to the disclosure can have a low dark current density, a high external quantum efficiency, and a high specific detectivity. An electronic device including the hole-blocking layer, the first self-assembled monolayer, and the second self-assembled monolayer according to the disclosure can have a low dark current density, a high external quantum efficiency, and a high specific detectivity.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a first electrode;
a second electrode on the first electrode;
a semiconductor layer between the first electrode and the second electrode;
an electron blocking layer between the semiconductor layer and the second electrode; and
a first self-assembled monolayer between the first electrode and the semiconductor layer,
wherein the first self-assembled monolayer comprises a compound represented by Formula (1) below:
X—R²—Si(OR¹)₃ (1),
wherein in Formula (1), R¹ are each independently a C₁-C₅ alkyl group;
R² is a C₁-C₂₀ alkylene group; and
X is an electron withdrawing group.

2. The electronic device as claimed in claim 1, wherein in Formula (1), X is a group selected from a group consisting of a hydroxyl group, a C₂-C₂₀ alkynyl group,- NO₂, —CN, —CF₃, —CCl₃, —CBr₃, —CI₃, and —COOH.

3. The electronic device as claimed in claim 1, further comprising a hole- blocking layer between the first self-assembled monolayer and the first electrode.

4. The electronic device as claimed in claim 3, wherein the hole-blocking layer comprises a surface comprising hydroxyl groups.

5. The electronic device as claimed in claim 3, wherein the hole-blocking layer comprises a material selected from a group consisting of aluminum-doped zinc oxide (AZO); poly{9,9-dimethyl-10-(9-(4-vinylbenzyl)-9H-carbazol-3-yl)-9,10- dihydroacridine} (P-CzAc); N-([1,1′-biphenyl]-4-yl)-N-(4-(dibenzo[b,d]thiophen-2- yl)phenyl)dibenzo[b,d]thiophen-2-amine (DBTA); 3,5-di-9H-carbazol-9-yl-N,N- bis[4-[6-[(3-ethyl-3-oxetanyl)methoxy]hexyl]oxy]phenyl]benzenamine (Oxe- DCDPA); poly[(9,9-dioctylfluorenyl-2,7-diyl)-co-(4,4′-(N-(diphenylamine))-(2- cyanoisopropylphenyl))] (iPrCNp/pCNPr-TFB); N4,N4-di(biphenyl-4-yl)-N4′- (naphthalen-1-yl)-N4′-phenyl-biphenyl-4,4′-diamine; 2,2′-dimethyl-N4,N4,N4′,N4′- tetra-m-tolylbiphenyl-4,4′-diamine; 2,2′-bis(N,N-di-phenyl-amino)-9,9- spirobifluorene; 2,2′-bis[N,N-bis(biphenyl-4-yl)amino]-9,9-spirobifluorene; N,N′- bis(phenanthren-9-yl)-N,N′-bis(phenyl)-benzidine; 2,2′,7,7′-tetrakis[N- naphthalenyl(phenyl)-amino]-9,9-spirobifluorene; N4,N4′-bis(9,9-dimethyl-9H- fluoren-2-yl)-N4,N4′-diphenylbiphenyl-4,4′-diamine; tris(phenylpyrazole)iridium; 2,2′,7,7′-tetrakis(N,N-diphenylamino)-2,7-diamino-9,9-spirobifluorene; N,N′- bis(naphthalen-1-yl)-N,N′-bis(phenyl)-2,7-diamino-9,9-diphenyl-fluorine; N,N′- bis(3-methylphenyl)-N,N′-bis(phenyl)-2,7-diamino-9,9-diphenyl-fluorine; N,N′- bis(naphthalen-1-yl)-N,N′-bis(phenyl)-2,7-diamino-9,9-dimethyl-fluorine; N,N′- bis(3-methylphenyl)-N,N′-bis(phenyl)-2,7-diamino-9,9-dimethyl-fluorine; 9,10- dihydro-9,9-dimethyl-10-(9-phenyl-9H-carbazol-3-yl)-acridine; 4,4′- (diphenylmethylene)bis(N,N-diphenylaniline); N4,N4′-di(naphthalen-1-yl)-N4-(4- octylphenyl)-N4′-phenylbiphenyl-4,4′-diamine; poly[N,N′-bis(4-butylphenyl)-N,N′- bis(phenyl)-benzidine]; N,N′-bis(naphthalen-1-yl)-N,N′-bis(phenyl)-2,2′- dimethylbenzidine; or a combination thereof.

6. The electronic device as claimed in claim 3, further comprising a second self- assembled monolayer between the hole-blocking layer and the first electrode, wherein the second self-assembled monolayer is different from the first self-assembled monolayer.

7. The electronic device as claimed in claim 6, wherein the second self- assembled monolayer comprises a compound represented by Formula (2) below:
Ar—R⁴—Si(OR³)₃ (2),
wherein in Formula (2), R³ are each independently a C₁-C₅ alkyl group;
R⁴ is a C₁-C₂₀ alkylene group; and
Ar is a group comprising a resonance structure.

8. The electronic device as claimed in claim 7, wherein in Formula (2), Ar is a substituted or unsubstituted C₆-C₂₀ aryl group, and at least one substituent of each of the substituted C₆-C₂₀ aryl group is one of a hydroxyl group, a deuterium atom, a tritium atom, a halogen atom, —CN, and a C₁-C₅ alkyl group.

9. The electronic device as claimed in claim 8, wherein the compound represented by Formula (2) is a compound selected from a group consisting of pentafluorophenyl triethoxysilane, phenyl triethoxysilane, pentafluorophenyl trimethoxysilane, and phenyl trimethoxysilane.

10. The electronic device as claimed in claim 6, wherein the second self- assembled monolayer is formed by a vacuum vapor deposition process.

11. The electronic device as claimed in claim 1, wherein the first electrode comprises a surface comprising hydroxyl groups.

12. The electronic device as claimed in claim 11, wherein the first electrode comprises a transparent conductive oxide.

13. The electronic device as claimed in claim 12, wherein the first electrode comprises indium tin oxide (ITO).

14. The electronic device as claimed in claim 1, wherein the first self-assembled monolayer is formed by a vacuum vapor deposition process.

15. The electronic device as claimed in claim 1, wherein the semiconductor layer comprises an electron donor material and an electron acceptor material.

16. The electronic device as claimed in claim 15, wherein the electron donor material comprises a material selected from a group consisting of a conjugated polymer;
a diketopyrrolopyrrole-based material; a 4,8-bis(5-(2-ethylhexyl)thiophen-2- yl)benzo[1,2-b: 4,5-b′]dithiophene-based material; a 2,1,3-benzoselenadiazole-based material; a 2,1,3-benzothiadiazole-based material; or a combination thereof.

17. The electronic device as claimed in claim 15, wherein the electron acceptor material comprises a material selected from a group consisting of a fullerene material; an indacenodithienothiophene (IDTT)-based material; a rhodanine-based material; Y6;or a combination thereof.

18. The electronic device as claimed in claim 1, wherein the electron blocking layer comprises a material selected from a group consisting of nickel oxide (NiO); 2,9- bis[3-(dimethyloxidoamino)propyl]anthra[2,1,9-def:6,5,10-d′e′f′]diisoquinoline- 1,3,8,10(2H,9H)-tetrone (PDINO); poly[[2,7-bis(2-ethylhexyl)-1,2,3,6,7,8- hexahydro-1,3,6,8-tetraoxobenzo[lmn][3,8]phenanthroline-4,9-diyl]-2,5- thiophenediyl[9,9-bis[3′((N,N-dimethyl)-N-ethylammonium)]-propyl]-9H-fluorene- 2,7-diyl]-2,5-thiophenediyl] (PNDIT-F3N-Br); poly[(9,9-bis(3′-((N,N-dimethyl)-N- ethylammonium)-propyl)-2,7-fluorene)-alt-2,7-(9,9-dioctylfluorene)]dibromide (PFN- Br); or a combination thereof.

19. The electronic device as claimed in claim 18, wherein the electron blocking layer comprises nickel oxide (NiO).

20. The electronic device as claimed in claim 18, wherein the electron blocking layer further comprises a non-polar solvent.
